(19) United States
(12) Patent Application Publication
(10) Pub. No.: US 2004/0231719 A1
(43) Pub. Date: Nov. 25, 2004

(54) Components based on melanin and melanin-like bio-molecules and processes for their production

(76) Inventor: Paul Meredith, Pullenvale (AU)

Correspondence Address: WORKMAN NYDEGGER (F/K/A WORKMAN NYDEGGER & SEELEY), 60 EAST SOUTH TEMPLE, 1000 EAGLE GATE TOWER, SALT LAKE CITY, UT, 84111, US

(21) Appl. No.: 10/491,224

(22) PCT Filed: Sep. 27, 2002
(86) PCT No.: PCT/AU02/01327

(30) Foreign Application Priority Data
Sep. 28, 2001 (AU) PR 7954

(51) Int. Cl. C08J 3/00; C08L 1/00; H01L 31/00; C08K 3/00

(52) U.S. Cl. 136/263; 523/106

(57) ABSTRACT

A regenerative photovoltaic cell (1) producing a visible light-induced photocurrent comprises a transparent or translucent first substrate (2) having a back surface coated with an indium tin oxide (ITO) layer (4), a nano-structured photoanode (5) comprising an n-type semiconductor (6), such as titanium dioxide, coated with a broad band absorbing melanin-like material (7), a second substrate (8) with a carbon/platinum coating (9) forming a counter cathode and a liquid electrolyte (14) between the photoanode and cathode, said electrolyte re-oxidising the melanin-like material (7) after it has absorbed incident radiation, thus returning it to the ground state. A p-i-n type photovoltaic cell is also exemplified in addition to other electronic devices employing melanin-like materials and processes for the production of mechanically stable, flexible films of melanin-like material for use in electronic devices.

### FIELD OF THE INVENTION

The invention relates to components based on melanin and melanin-like bio-molecules and processes for the production of said components. Generally, the invention relates to photovoltaic, optoelectronic, semiconductor and electronic devices comprising melanin or melanin-like materials. Particularly, but not exclusively, the invention relates to regenerative photovoltaic cells comprising melanin or melanin-like bio-molecules as the light absorbing/photoconductive material.

### BACKGROUND TO THE INVENTION

The technology of photovoltaic, optoelectronic, semiconductor and other such electronic devices is dominated by inorganic materials such as silicon, gallium arsenide (GaAs) and the like. However, the discovery of electrical conductivity in organic polymers in the 1970's has provided potential alternatives to the inorganic materials.

“Soft” organic materials possess a number of potential advantages over the “harder” inorganic materials, such as their robustness and mechanical flexibility, their potentially easier processing, reduced cost and, importantly, their improved biocompatibilty.

The various characteristics of conducting organic materials, suitable processes for their production and their applications are the subject of numerous patents. For example, U.S. Pat. No. 4,488,943 (Skotheim) discloses methods of manufacturing polymer blends and their use in photochemical cells for the conversion of solar energy to electricity and U.S. Pat. No. 5,201,961 (Yoshikawa et al.) discloses a photovoltaic device containing organic material layers and having high conversion efficiency.

Many patents disclose the properties of synthetic polyindoles and their use in a variety of devices. For example, U.S. Pat. No. 5,290,891 (Billaud et al.) describes a process for preparing polymers based on polyindoles by chemical polymerisation of indole in the presence of an oxidizing agent and a solvent. U.S. Pat. No. 5,290,891 also discloses electro-conductive devices containing the prepared polymers.

However, one drawback of using such synthetic materials, particularly in photovoltaic applications, is its limited photon absorption capability. Since the efficiency of the device is directly related to the number of photons absorbed, synthetic polyindoles are not ideal for such applications.

Biopolymers represent a class of materials distinct from these synthetic compounds in that they are found naturally occurring throughout the biosphere. Biopolymers offer the added advantage over organic synthetic materials of ultimate biocompatibility. Additionally, since they occur in nature, there is often a ready supply of raw material.

In contrast to organic synthetic materials, there are few patents that describe the use of biopolymers in high technology devices as electronic or photoactive components. Of these, there are several examples that describe the use of functionalised biopolymers, such as quinones, flavins, pterins and polyamino acids as electron transfer agents in a number of different devices. For example, DE 1231610 (Saturo et al.) discloses an artificially functionalised biopolymer, wherein the functional group comprises an electron transfer capability such that several functional groups are retained in order to achieve the desired electrical properties. The biopolymer is specified as a cyclochrome, flavodoxin, ferredoxin, rubredoxin, thioredoxin, plastocyanine, azurla, oxidase, dehydrogenase, reductase, hydrogenase, peroxidase, hydroperoxidase or oxygenase, and the functional group with electron transfer capability is specified as a flavin mononucleotide, metal porphyrin, metal phthalocyanine, ferrocene, porphyrin, phthalocyanine, quinone, isoallaxazin, pyridine nucleotide, biologen or derivatives of biologen, tetracyano-quinodimethane, metal atom or metal ion.

Similarly, U.S. Pat. No. 4,514,584 (Fox et al.) discloses an organic photovoltaic device wherein the photoactive electron donor component is a thermal condensation polymer of at least one monoaminodicarboxylic acid and the photo-active electron acceptor component is a thermal condensation polymer of at least one basic amino acid, such as diaminomonocarboxylic acid and wherein the polymers contain photo-active flavin and pterin pigments.

McGinness, Corey and Procter (Amorphous semiconductor switching in Melanins, McGinness et al., Science 183, p853, 1974), were the first to demonstrate that melanins were natural semiconductors and its electrical conductivity has been quantified by, for example, Osak et al., (I-V characteristics and electrical conductivity of synthetic melanin, Osak et al., Biopolymers 28, p1885, 1989). Trukhan et al., (Investigation of the photoconductivity of the pigment epithelium of the eye, Trukhan et al., Biofizika 18(2), p392, 1973), and Rosei et al., (Photoelectronic properties of synthetic melanins, synthetic Metals 76, p331, 1998), have also demonstrated that melanins are photoconductive.

U.S. Pat. No. 4,386,216 (McGinness) describes the use of polymers of quinone, semiquinone and hydroquinone for electrical energy storage and U.S. Pat. No. 5,252,628 (Constable et al.) describes a method of making photo-protective hydrophilic polymers combined with melanin pigments and their uses in ocular devices.

Serban and Nissenbaum (Light induced production of hydrogen from water by catalysis with ruthenium melanoidins, International Journal of Hydrogen Energy 26, p733, 2000) describe how a ruthenium containing melanoidin (an III-defined condensation product of amino acids and carbohydrates formed by the Browning reaction), was found to photocatalyse hydrogen production from water under ultra violet light illumination. However, polycondensates of amino acids and carbohydrates are not the subject of the current invention.

Oliveira et al., (Synthesis, characterisation and properties of a melanin-like/vanadium pentoxide hybrid compound, Journal of Materials Chemistry 10, p371. 1999 & Electrochromic and conductivity properties: a comparative study between melanin-like/V₂O₅.nH₂O and polyanaline/V₂O₅.nH₂O hybrid materials, Journal Non-Crystalline Solids 273, p193, 2000), have described Vanadium Pentoxide/melanin-like hybrid materials as having potential applications in optics and electronic devices. However, in such materials the melanin-like molecules modify the conductivity of the Vanadium Pentoxide host material and the melanin-like molecules themselves play a non-conducting role.

There is a need for organic biopolymers to be utilized in photovoltaic, optoelectronic, semiconductor and other such electronic devices, yet the prior art has identified only a comparatively small range of materials generally suitable for such applications, many of which lack the desired characteristics for specific applications.

### DISCLOSURE OF THE INVENTION

In one form, although it need not be the only or indeed the broadest form, the invention resides in a photoelectric device having at least one photoactive element, said photoactive element comprising a melanin-like material.

The term melanin-like is used herein in relation to the invention to refer to melanin and to materials defined as oligomers or biopolymers derived from naturally occurring eumelanins, seplamelanin, neuromelanin, phaomelanin or allomelanins.

The melanin-like materials may be natural or synthetic monomeric, oligomeric or polymeric analogues of eumelanins, sepiamelanin, neuromelanin, phaomelanin or allomelanins and be selected from one or more of the following substances: an indolequinone, dihydroxyphenylalanine (DOPA), dihydroxyphenylalanine quinone, tyrosine, a catechol, a catechol amine, cyteinyldopa, or derivatives thereof.

The indolequinone may be dihydroxyindole, dihydroxyindole carboxylic acid, quinones, semiquinones, or hydroquinones.

Preferably, the melanin-like material is a biopolymeric material such as natural or synthetic eumelanin, phaomelanin, seplamelanin, neuromelanin, allomelanin or synthetic derivatives such as dopa eumelanin or polyhydroxyindole.

The melanin-like material may be doped with metal ions, such as copper, iron, chromium, zinc, or any other chelatable transition metal ion up to levels of approximately 20% by molecular weight in order to facilitate tuning of electronic properties of the melanin-like material.

The photoactive element may be in the form of at least one mechanically stable and flexible film. The film may have a thickness in the range of a single molecular layer to approximately 1 mm depending upon the relevant application.

The photoactive element may be a photoanode comprising an electrically conducting substrate coated with the melanin-like material. The photoanode may be a colloid.

The electrically conducting substrate may comprise one of the following materials: a wide band gap rare earth oxide, a metal, a crystalline semiconductor, an amorphous semiconductor, a conducting polymer, a semi-conducting polymer, an organic material.

Suitably, the electrically conducting substrate may be an n-type semiconductor.

Suitably, the electrically conducting substrate may be indium tin oxide (ITO), fluorine doped tin oxide, or titanium dioxide.

Suitably, the melanin-like material is p-doped.

In another form, the invention resides in a photoanode comprising a titanium dioxide substrate coated with a melanin-like material.

In a further form, the invention resides in a photovoltaic cell having a photoanode comprising a titanium dioxide substrate coated with a melanin-like material.

The photovoltaic cell may further comprise a counter cathode and a liquid electrolyte been the photoanode and the counter cathode.

Suitably, the counter cathode is capable of injecting an electron into the liquid electrolyte. Suitably, the counter cathode material may be one of a low work function metal, a semiconductor or a thin catalytic layer of carbon.

Suitably, a visible light-induced photocurrent is generated by the photovoltaic cell in the absence of an external current.

In a yet further form, the invention resides in a photovoltaic cell comprising:

a p-type semiconducting element:

an n-type semiconducting element; and

an intrinsic, semiconducting photon-absorbing element disposed between said p-type semiconducting element and said n-type semiconducting element, wherein said intrinsic, semiconducting photon-absorbing element comprises a melanin-like material.

Suitably, the p-type semiconducting element may be one of an organic or inorganic wide band gap p-type semiconductor.

Preferably, the photovoltaic cell comprises a cathode capable of injecting an electron into the p-type wide band gap semiconducting element.

In another form, the invention resides in an electrical connector comprising a melanin-like material.

The electrical connector may be conducting or semiconducting.

The melanin-like material may be patterned or formed onto an electrically insulating surface.

In another form, the invention resides in a process for producing mechanically stable, thin films of melanin-like material for use in electronic devices, said process including the step of:

low temperature chemical or physical vapour deposition under vacuum conditions, wherein, for chemical vapour deposition, solid, liquid or gas precursors of melanin-like material are used as a source material and, wherein, for physical vapour deposition, solid precursors of melanin-like material are used as the source material.

The melanin-like material may comprise one or more monomers, oligomers, biopolymers or hetero biopolymers of indolequinones, dihydroxyphenylalanine (DOPA), dihydroxyphenylalanine quinone, tyrosine, catechols, catechol amines, cyteihyldopa.

In yet another form, the invention resides in a process for producing mechanically stable, thin films of melanin-like material for use in electronic devices including the step of:

reactive/passive spin or dip coating liquid precursors or liquid solutions of at least one melanin-like material.

The melanin-like material may comprise one or more monomers, oligomers, biopolymers or hetero biopolymers of indolequinones, dihydroxyphenylalanine (DOPA), dihydroxyphenylalanine quinone, tyrosine, catechols, catechol amines, cyteinyldopa.

The processes may further include the step of:

co-depositing the melanin-like material within a host polymer matrix to form a composite film.

Suitably, the host polymer may be one of an insulating, semiconducting or electrically conducting organic polymer.

### BRIEF DESCRIPTION OF THE DRAWINGS

To assist in understanding of the invention and to enable a person skilled in the art to put the invention into practical effect preferred embodiments will now be described by way of example only with reference to the accompanying drawings, wherein:

FIG. 1 shows a schematic cross-section of a photoelectric device having a photoactive element comprising a melanin-like material in accordance with one form of the present invention;

FIG. 2 shows structural formulae of examples of suitable melanin-like precursor materials based upon indolequinones for the photoelectronic device shown in FIG. 1;

FIG. 3 shows an energy level diagram for a titanium dioxide-melanin-like material photoanode interface used in a photovoltaic cell as it relates to the particular photo-electrochemical device application shown in FIG. 1;

FIG. 4 shows a graph comparing the variation of photocurrent with illumination wavelength for a photovoltaic cell with a bare titanium dioxide photoanode and a melanin-sensitised titanium dioxide photoanode according to another form of the present invention;

FIG. 5 shows a schematic cross-section of a photovoltaic device of the all solid state extremely thin absorber (η) design having a photoactive element comprising a melanin-like component according to a further form of the present invention; and

FIG. 6 shows an energy level diagram for an (η) photovoltaic cell of the type shown in FIG. 5.

### DETAILED DESCRIPTION OF THE INVENTION

The Applicant has identified that melanin-like materials as defined in this patent application are particularly suited for photoactive devices, such as photovoltaic and optoelectronic devices and also for other semiconductor and electronic devices.

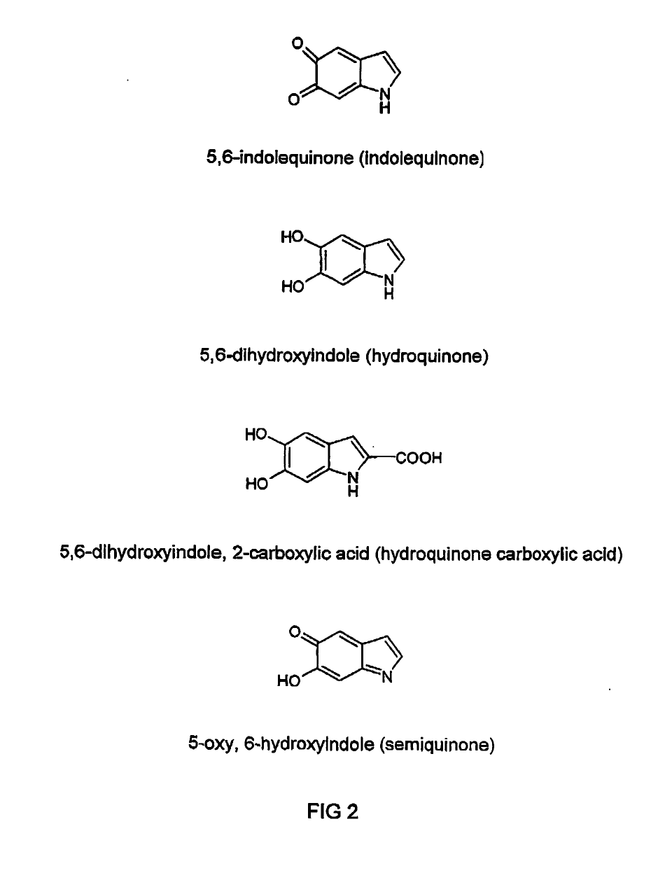

The melanin-like materials that may be employed in such devices include melanin and materials defined as oligomers or biopolymers derived from naturally occurring eumelanins, sepiamelanin, neuromelanin, phaomelanin or allomelanins according to the classification of Nicolaus (Melanins, Herman, Paris, 1968). Additionally, they may be natural or synthetic monomeric, oligomeric or polymeric analogues of these materials containing or derived from indolequinones (such as dihydroxyindole, is dihydroxyindole carboxylic acid, quinones, semiquinones, or hydroquinones), dihydroxyphenylalanine (DOPA), dihydroxyphenylalanine quinone, tyrosine, catechols (derivatives of 1,2 dihydroxybenzene), catechol amines, cyteinyldopa, or mixtures thereof. The structures of some of these materials are shown in FIG. 2.

The melanin-like material is preferably a biopolymeric material such as natural or synthetic eumelanin, neuromelanin, allomelanin, phaomelanin or sepia melanin, or synthetic derivatives such as dopa eumelanin or polyindoloquinone and these are particularly suited to such applications.

In the case of natural melanin-like materials, methods of extracting such materials from native tissue are known to those skilled in the art. Such methods are covered in detail in publications such as Arnaud, J. C. & Bore, P., Isolation of Melanin Pigments From Human Hair, J. Soc. Cosmet. Chem., 32, p137-152, 1981, and involve the progression digestion of non-melanin related native accompanying tissue using a suitable enzyme, such as protease, followed by chemical and physical separation and purification of the desired melanin-like biopolymer.

If the melanin-like materials are to be synthesised, then one of the methods based upon the auto-oxidation of dihyrophenylaline may be used. These synthetic routes are commonly known, and details are given literature such as Korytowski, W., Pilas, B., Sama, T. & Kalyanaraman, B., Photoinduced Generation of Hydrogen Peroxide & Hydroxyl Radicals in Melanin, Photochem. Photobiol., 45(2), p185 190, 1987, or Menon, I. A., Leu, S. L. & Haberman, H. F., Electron Transfer Properties of Melanin: Optimum Conditions and the Effects of Various Chemical Treatments, Can. J. Biochem., 55, p783-787, 1977.

The melanin-like materials may be in the form of mechanically stable, robust, thin, flexible films, depending on the application, which may be achieved by the aforementioned extraction or synthesis processes combined with chemical or physical vapour deposition, or reactive/passive dip or spin coating onto a suitable substrate. The films may have a thickness in the range of a single molecular layer to approximately 1 mm, depending on the application.

Alternatively, the melanin-like material may be deposited on or co-deposited with a colloidal form of a suitable nanoporous semiconducting oxide, for example titanium dioxide, to produce very large surface area photoelectrodes suitable for photovoltaic or other device applications.

Alternatively, the melanin-like material may be deposited on co-deposited within a host polymer matrix to form a composite film of the pre-requisite and desired mechanical, structural, optical, electrical and/or chemical properties. The host polymer may be an insulating, semiconducting or electrically conducting organic polymer.

In accordance with one form of the present invention, the melanin-like material may form a conducting or semiconducting electrical connector between two elements in a circuit. The melanin-like material may be formed onto a suitable electrically insulating surface and may be patterned. The melanin-like material functions as a soft electronic medium and as such offers greater scope in electronic devices due to the flexibility, long term stability and other characteristics of the melanin-like material as described herein in relation to other embodiments of the present invention.

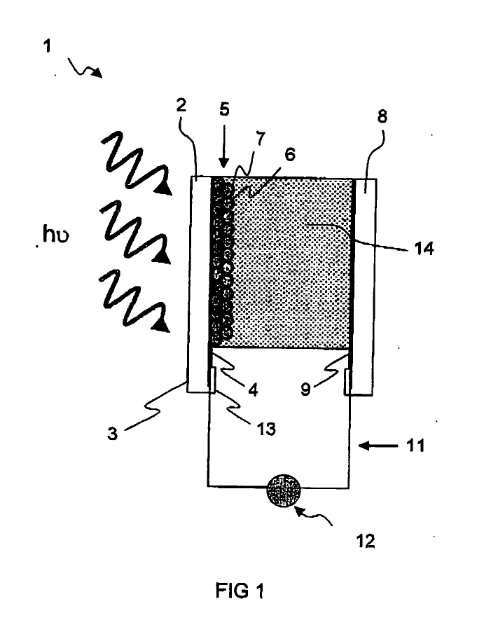

An example of a photovoltaic device in accordance with the present invention is shown in FIG. 1, which is based on an example of a so-called Grätzel Cell, as disclosed in, for example, U.S. Pat. No. 6,728,487 (Grätzel et al.).

With reference to FIG. 1, the cell 1 comprises a transparent or translucent first substrate 2 having a front surface 3. The back surface of the substrate 2 may be coated with a layer 4 of suitable transparent conducting material, such as indium tin oxide (ITO). A photoanode 5 is formed from an electrically conducting substrate 6 sensitised by a melanin-like material 7. The electrically conducting substrate 6 may be in the form of a wide band gap rare earth oxide, a metal, a crystalline semiconductor, an amorphous semiconductor, a conducting polymer, a semi-conducting polymer or an organic material. In a preferred embodiment, the photoanode 5 comprises an n-type semiconductor 6, such as titanium dioxide, coated with a broad band absorbing melanin-like biopolymer 7. The n-type semiconductor 6 may be in a colloidal state and form a percolated network. Alternatively, the electrically conducting substrate 6 may be indium tin oxide (ITO) or fluorine doped tin oxide. A second substrate 8, which may also be transparent or translucent, comprises a carbon/platinum coating 9, which forms a counter cathode.

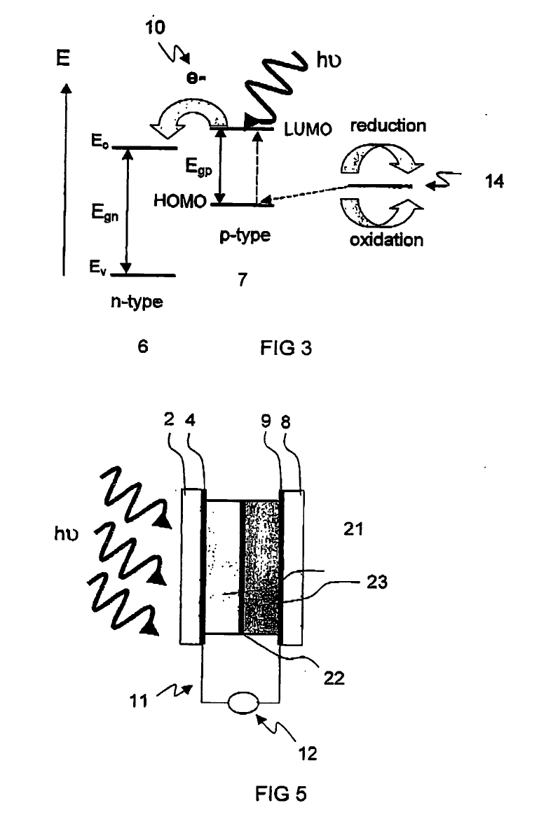

With additional reference to FIG. 3, incident UV and visible photons of varying energies ho are absorbed by the biopolymer 7, and a photoelectron 10 is injected into the conduction band of energy Eₒ of the wide band gap semiconductor 6. In so doing, the biopolymer 7 is reduced. This process is described in more detail hereinafter.

If the connectivity of the percolated semiconductor network is sufficient, the photoelectron 10 may be transported away and utilised in an external circuit 11 comprising a load 12 via metal contacts 13, as shown in FIG. 1. The circuit is completed by the electrolyte 14, which acts as a mediator and re-oxidises the biopolymer 7, returning it to the ground state. The electrolyte 14 may comprise any solid or liquid redox couple with a suitable redox potential. In the example shown, a liquid electrolyte was employed comprising an iodine-trilodide redox couple in water free ethylene glycol.

Hence, the photovoltaic device 1, in accordance with the present invention, is a regenerative photo-electrochemical cell, i.e. the cell 1 produces a photocurrent under visible light illumination as well as UV illumination without the application of an external electric field.

It will be appreciated that the arrangement of elements of the photovoltaic device shown schematically in FIG. 1 is given by way of example only and variations to the specific embodiment will nonetheless fall within the scope of the invention. For example, the area shown as representing the liquid electrolyte 14 comprising the biopolymer coated semiconductor 6 may extend the full length of the transparent substrate 2 in order to maximize absorption of photons incident on the front surface 3 of the transparent substrate.

FIG. 2 shows examples of the indolequinone monomer units that may make up the melanin-like bio-molecules, oligomers, biopolymers and hetero-biopolymers. The monomers may be linked though positions 2, 3, 4 or 7 to form oligomers and higher order molecules.

By controlling the level of metal ion doping (for example the level of copper or other chelatable transition metal ion at levels ranging between 0 and approximately 20% by molecular weight) in the melanin-like material, the molecular weight/monomer ratio and the water content thereof, the electrical conductivity and semi-conducting properties of the melanin-like material may be tuned to the particular application. Details of the effects of varying these parameters upon the electrical properties of such materials can be found in literature such as Jastrzebska, M. M., Isotalo, H., Paloheimo, J., Stubb, H. & Pilawa, B., Effect of Cu²⁺ ions on semiconductor properties of synthetic DOPA melanin polymer, J. Biomater. Sci, Polymer Ed., 9(7), 781, 1996 or Jastrzebska, M. M., Isotalo, H., Paloheimo, J. & Stubb, H., Electrical conductivity of synthetic DOPA-melanin polymer for different hydration states and temperatures, J. Biomater. Sci, Polymer Ed., 7(7), 577, 1995).

Certain critical design parameters need to be considered when the invention is used as a photoactive component within a photon harvesting device. The theory behind photo-induced charge generation in semiconductors is well known to those skilled in the art. However, the details of photo-induced charge generation in organic heteropolymers is less well understood, but, nevertheless is covered in some advanced texts on the subject. See for example: Conjugated Oligomers, Polymers, and Dendrimers: From Polyacetylene to DNA, Proc. 4^{th} Francqul Colloqium, Jean-Luc Bredas (Ed), 1998.

To illustrate the theory behind the current invention, consideration should be given to the device shown in FIG. 1. In this device, the melanin-like material 7 acts as a visible photosensitiser to the wide band gap semiconducting material 6, which in the example is titanium dioxide. The wide band gap semiconducting material 6 only absorbs ultra violet photons, which is one of the aforementioned problems with the conventional Grätzel Cell. This is highly undesirable for a solar cell since a significant amount of the sun's energy reaches the earth as visible radiation. In the present invention, the melanin-like material absorbs substantially all photons in the ultra violet and visible portions of the solar spectrum, and so enhances the efficiency of the device.

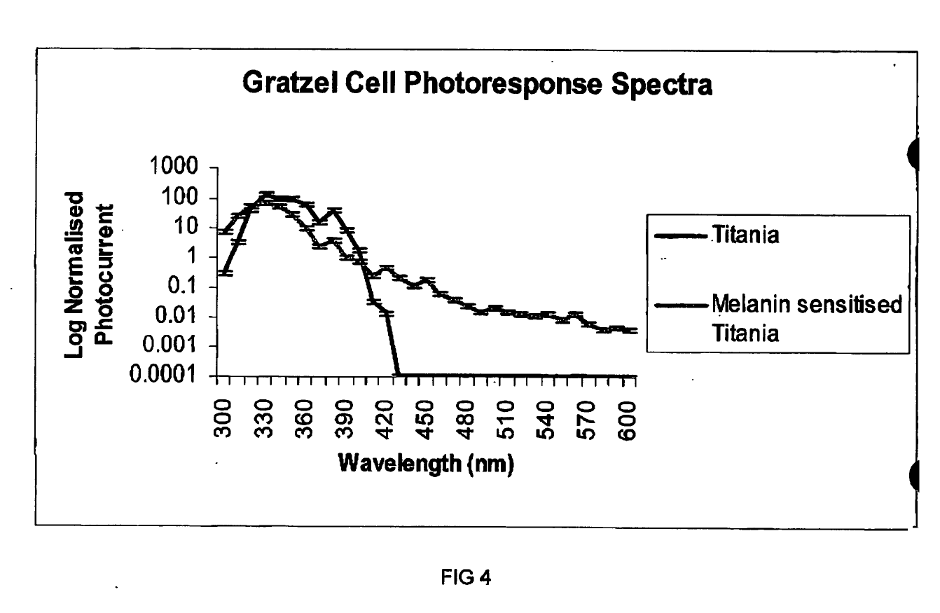

Experimental results illustrating absorption in the visible region of the spectrum are shown in FIG. 4. The experiment was conducted using a cell of the type shown in FIG. 1, which employed mesoporous titanium dioxide as the n-type semiconductor photoanode, which was sensitised with a synthetic polydopa melanin analogue. The photocurrent was measured as a function of the illumination wavelength and compared with a bare, unsensitised titanium dioxide photoanode.

FIG. 4 illustrates the absence of photoconduction in the bare, unsensitised titanium dioxide photoanode above approximately 400 nm, which is consistent with the band edge (limit of absorption) lying at 370 nm for titanium dioxide, i.e., titanium dioxide only absorbs ultra violet photons. In contrast, the melanin-sensitised titanium dioxide photoanode 5 in the cell of the present invention exhibit a measurable, visible light-induced photocurrent in the wavelength range of approximately 400-600 nm as well as in the UV region.

The process is now explained with reference to FIG. 3, which shows a simple band model for the titanium dioxide melanin interface for use in a photovoltaic cell based upon the Grätzel concept. This example is given by way of illustration of the theory and operation of the invention in relation to its photoconductive role. In FIG. 3, the nomenclature is as follows:

E_{c}=conduction band TiO₂

Eᵥ=valence band TiO₂

E_{gn}=band gap TiO₂

E_{gp}=band gap melanin

LUMO=Lowest Unoccupied Molecular Orbital melanin (π*)

HOMO=Highest Occupied Molecular Orbital melanin (π)

Excited electrons produced by the absorption of radiation in the melanin-like material 7 must be injected into the conduction band E_{c} of the wide band gap semiconductor material 6 in order to be transferred to the external circuit 11 and used to drive the load 12 or be stored in a battery (not shown) for later use. For this to occur for all photons in the ultra violet and visible portions of the solar spectrum, the energy of the lowest unoccupied molecular orbital (i.e. the lowest energy level corresponding to a delocalised photo-excited electron), often called the LUMO level, must exceed that of the conduction band Eₒ of the wide band gap semiconductor material 6. If such is the case, there is a high probability that the photo-excited electron 10 will be injected into the conduction band E_{c} of the wide band gap semiconductor 6, and hence be removed for external use. In the example shown in FIG. 3, the melanin-like material 7 has been p-type doped, and has a band gap E_{gp} of ˜1.5 eV. The wide band gap semiconducting material 6 in this example is titanium dioxide, and has a band gap E_{gn} of 3.2 eV.

The conventional photo-electrochemical Grätzel cell is one device that would benefit from the invention detailed in this patent application. Currenty, Ruthenium based dyes are used for the visible photon harvesting material, which are both complex and expensive. Furthermore, the combination of TiO₂ and Ruthenium does not absorb all of the available visible and ultra violet solar photons.

In contrast, melanin-like materials are broadband absorbers and are more efficient than the aforementioned Ruthenium based dyes. In addition, melanin-like materials are cheaper to produce and since they may be derived from biological material, they are non-toxic and offer ultimate biocompatibility. The flexibility of the melanin-like films also provides greater scope in the construction of the devices.

These advantages of the melanin-like materials render them more suitable for such applications than similar synthetic materials such as polyindoles.

In addition to these advantages, the melanin-like materials have improved long term stability to photo and chemical oxidation due to the inherent free radical scavenging and antoxidant characteristics of melanin and melanin-like materials. By virtue of transition metal doping, these materials also offer ease of tuning of the electronic properties by allowing the adjustment of the band gap, conductivity type, the carrier density and mobility, the defect density and the electrical conductivity.

All of these advantages could be likewise utilised in an alternative embodiment of the invention known as the extremely thin absorber (η) photovoltaic cell 20, an example of which is shown in FIG. 5. Like features of the cells in FIGS. 1 and 5 are referred to by common reference numerals.

This device is of the p-i-n type design and consist of an n-type semiconducting material 21, a thin, intrinsic semiconducting photon absorbing layer 22 and a p-type semiconducting material 23. Both p- and n-type semiconducting materials 21, 23 may be organic or inorganic, but are preferably mechanically flexible, organic materials such as conducting polymers. The intrinsic photon absorbing material 22 consists of a melanin-like material. The p-i-n structure is supported on conducting, transparent substrates 2, 8, which may be similar to those described for the photo-electrochemical device shown in FIG. 1. Hence, substrate 2 may comprise a suitable transparent conducting layer, such as indium tin oxide (ITO) layer 4 and substrate 8 may comprise a carbon/platinum coating 9.

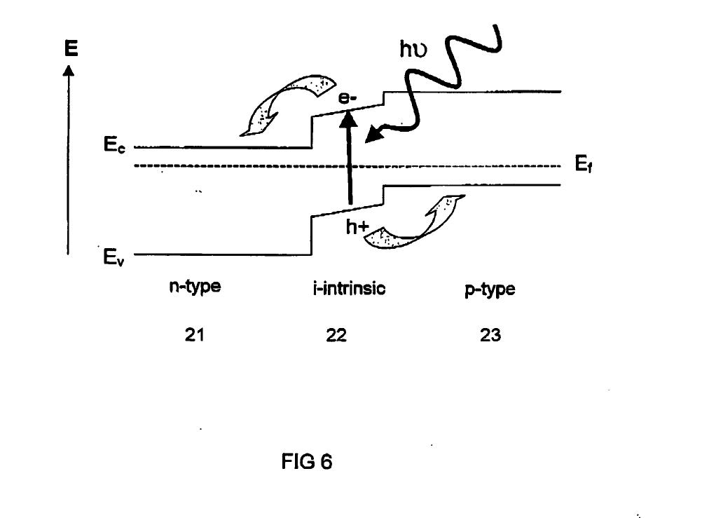

The mode of action of this all solid-state device may be understood with reference to the energy diagram shown in FIG. 6. A photon of energy hυ is absorbed by the melanin-like intrinsic layer 22. The photon generates an electron-hole pair (e−, h+), and under the action of the internal electric field established by joining p- and n-type materials 21, 23 respectively, the electron is transferred to the n-type material 21 and the hole to the p-type material 23. In such a way, the electron can be extracted and used in an external circuit 11. The cell 20 is also regenerative in that the p-type material 23 completes the circuit by extracting the hole.

Throughout the specification the aim has been to describe the invention without limiting the invention to any one embodiment or specific collection of features. Persons skilled in the relevant art may realize variations from the specific embodiments that will nonetheless fall within the scope of the invention.

1. A photoelectric device having at least one photoactive element, said photoactive element comprising a melanin-like material.

2. The photoelectric device of claim 1, wherein the melanin-like material is an oligomer or biopolymer derived from one or more of the following naturally occurring substances, eumelanins, seplamelanin, neuromelanin, phaomelanin, allomelanins.

3. The photoelectric device of claim 1, wherein the melanin-like material is a natural or synthetic monomeric, oligomeric or polymeric analogue of eumelanins, seplamelanin, neuromelanin, phaomelanin, allomelanins.

4. The photoelectric device of claim 3, wherein the melanin-like material is selected from a polymer or heteropolymer of one or more of the following substances: an indoloquinone, tyrosine, dihydroxyphenylalanine (DOPA), dihydroxyphenylalanine quinone, a catechol, a catechol amine, cyteinyldopa.

5. The photoelectric device of claim 3, wherein the melanin-like material is selected from a polymer or heteropolymer of one or more derivatives of the following substances: an indolequinone, tyrosine, dihydroxyphenylalanine (DOPA), dihydroxyphenylalanine quinone, a catechol, a catechol amine, cyteinyldopa.

6. The photoelectric device of claim 4, wherein the indolequinone is dihydroxyindole, dihydroxyindole carboxylic acid, a quinone, a semiquinone, or a hydroquinone.

7. The photoelectric device of claim 5, wherein the indolequinone is dihydroxyindole, dihydroxyindole carboxylic acid, a quinone, a semiquinone, or a hydroquinone.

8. The photoelectric device of claim 1, wherein the melanin-like material is doped with a metal ion.

9. The photoelectric device of claim 8, wherein the metal ion is a chelatable transition metal ion.

10. The photoelectric device of claim 8, wherein a level of metal ion doping in the melanin-like material is up to approximately 20% by molecular weight.

11. The photoelectric device of claim 1, wherein the photoactive element comprises at least one mechanically stable and flexible film.

12. The photoelectric device of claim 11, wherein a thickness of the film is in the range of a single molecular layer to approximately 1 mm.

13. The photoelectric device of claim 1, wherein the photoactive element is a photoanode comprising an electrically conducting substrate coated with the melanin-like material.

14. The photoelectric device of claim 13, wherein the photoanode is a colloid.

15. The photoelectric device of claim 13, wherein the electrically conducting substrate comprises one of the following materials: a wide band gap rare earth oxide, a metal, a crystalline semiconductor, an amorphous semiconductor, a conducting polymer, a semiconducting polymer, an organic material.

16. The photoelectric device of claim 13, wherein the electrically conducting substrate is an n-type semiconductor.

17. The photoelectric device of claim 13, wherein the melanin-like material is p-doped.

18. A photoanode comprising a titanium dioxide substrate coated with a melanin-like material.

19. A photovoltaic cell comprising the photoanode of claim 18.

20. The photovoltaic cell of claim 19, further comprising:
a counter cathoda; and
an electrolyte between said photoanode and said counter cathode.

21. The photovoltaic cell of claim 20, wherein the counter cathode material is one of a low work function metal, a semiconductor, or a thin catalytic layer of carbon.

22. The photovoltaic cell of claim 19, wherein a visible light-induced photocurrent is generated in the absence of an external current.

23. A photovoltaic cell comprising:
a p-type semiconducting element;
an n-type semiconducting element; and
an intrinsic, semiconducting photon-absorbing element disposed between said p-type semiconducting element and said n-type semiconducting element, wherein said intrinsic, semiconducting photon-absorbing element comprises a melanin-like material.

24. The photovoltaic cell of claim 23, wherein said p-type semiconducting element is one of an organic or inorganic wide band gap p-type semiconductor.

25. The photovoltaic cell of claim 24, further comprising a cathode capable of injecting an electron into the p-type semiconducting element.

26. A process for producing mechanically stable, thin films of melanin-like material for electronic devices, said process including the step of:
low temperature vapour deposition under vacuum conditions using precursors of melanin-like material as a source material.

27. The process of claim 26, wherein for physical vapour deposition, said precursors of melanin-like material are in a solid state.

28. The process of claim 26, wherein for chemical vapour deposition, said precursors of melanin-like material are in one of a solid, liquid or gas state.

29. The process of claim 26, wherein the melanin-like material comprises one or more monomers, oligomers, biopolymers, or hetero biopolymers of indolequinones, dihydroxyphenylalanine (DOPA), dihydroxyphenylalanine quinone, tyrosine, catechols, catechol amines, cyteinyldopa.

30. A process for producing mechanically stable, thin films of melanin-like material for electronic devices including the step of:
reactive/passive spin or dip coating one of liquid precursors or liquid solutions of at least one melanin-like material.

31. The process of claim 30, wherein the melanin-like material comprises one or more monomers, oligomers, biopolymers, or hetero biopolymers of indolequinones, dihydroxyphenylalanine (DOPA), dihydroxyphenylalanine quinone, tyrosine, catechols, catechol amines, cyteinyldopa.

32. The process of claim 30, further including the step of depositing the melanin-like material on or within a host polymer matrix to form a composite film.

33. The process of claim 32, wherein the host polymer is one of an insulating, semiconducting or electrically conducting organic polymer.

34. An electrical connector comprising melanin-like material, wherein said electrical connector is conducting or semiconducting.

35. The electrical connector of claim 34, wherein the melanin-like material is formed onto an electrically insulating surface.
